(19) United States
(12) Patent Application Publication
(10) Pub. No.: US 2011/0108107 A1
(43) Pub. Date: May 12, 2011

(54) Thin-Film Solar Battery Module and Method of Manufacturing the Same

(75) Inventors: Hiroto Uchida, Kanagawa (JP); Yuko Taguchi, Kanagawa (JP); Masashi Ueda, Kanagawa (JP); Michihiro Takayama, Kanagawa (JP)

(73) Assignee: ULVAC, INC., Kanagawa (JP)

(21) Appl. No.: 12/992,126

(22) PCT Filed: May 12, 2009
(86) PCT No.: PCT/JP2009/058855

§ 371 Date: Jan. 26, 2011

(30) Foreign Application Priority Data
May 15, 2008 (JP) 2008-128188

(51) Int. Cl. H01L 31/0224; H01L 31/18; H01L 31/04

(52) U.S. Cl. 136/256; 438/57

(57) ABSTRACT

[Object] To provide a thin-film solar battery module and a method of manufacturing the thin-film solar battery module that are capable of improving connection reliability of an external connection terminal and reducing connection resistance thereof.

[Solving Means] A thin-film solar battery module according to the present invention includes an insulating transparent substrate, a solar cell, and an external connection terminal. The solar cell includes a transparent electrode layer, a semiconductor layer, and a backside electrode layer. The external connection terminal includes a connection layer and a terminal layer and is arranged adjacently to the solar cell, the connection layer being formed on the surface of the transparent electrode layer and made of a single metal material layer, the terminal layer being laminated on the connection layer. With this structure, as compared to a case where the terminal connection layer is constituted to contain a semiconductor material, the adhesiveness between the transparent electrode layer and the terminal layer can be enhanced and the contact resistance between the transparent electrode layer and the terminal layer can be reduced.

### FIELD

The present invention relates to a thin-film solar battery module including an external connection terminal and a method of manufacturing the thin-film solar battery module.

### BACKGROUND

A thin-film solar battery module is an integrated body of a plurality of solar cells that are manufactured on a translucent substrate. The solar cell is formed of a first electrode layer made of a transparent conductive oxide formed on the translucent substrate, a semiconductor layer made of amorphous silicon or the like formed on the first electrode layer, and a second electrode layer (backside electrode) made of metal or the like formed on the semiconductor layer (see Patent Documents 1 and 2).

The first electrode layer, the semiconductor layer, and the second electrode layer are formed by vapor-deposition such as a CVD method and a sputtering method. After the respective layers are formed, the layers are laser-scribed on the translucent substrate to isolate the device into a plurality of cells, and then adjacent solar cells are connected in series (or in parallel). After that, the entire surfaces of the respective layers are sealed with a resin filling material, thus constituting a thin-film solar battery module.

Such a thin-film solar battery module includes, on the translucent substrate, an external connection terminal for taking out a voltage generated in the solar cells to the outside. The external connection terminal is formed at each of positive and negative electrode portions at which a potential difference therebetween within the solar cell is highest. Those external connection terminals are generally formed through formation of a film using a thin-film material and patterning that are used in a process of forming the solar cell.

In this regard, Patent Documents 1 and 2 disclose a method of manufacturing a lead attachment portion for external connection through a process of laser-scribing, after the first electrode layer, the semiconductor layer, and the second electrode layer are formed, the second electrode layer and the semiconductor layer to have a depth reaching the surface of the first electrode layer, and forming a plurality of lead connection trenches at intervals, a process of forming a solder bump while straddling the plurality of lead connection trenches, and a process of bonding lead wires to upper portions of the lead connection trenches via the solder bump.
Patent Document 1: Japanese Patent Application Laid-open No. 2006-319215
Patent Document 2: Japanese Patent Application Laid-open No. 2007-273908

### SUMMARY

### Problem to be Solved by the Invention

In the methods disclosed in Patent Documents 1 and 2, each of the lead connection trenches is formed to have a depth reaching a surface of the first electrode layer while extending from the second electrode layer, with respect to a laminated film constituted of the first electrode layer, the semiconductor layer, and the second electrode layer. With this, every structure formed between the lead connection trenches becomes a laminated body of the semiconductor layer and the second electrode layer.

However, the semiconductor layer has characteristics of relatively low adhesiveness with a metal layer, a conductive oxide layer, and the like. Therefore, since the structure formed between the lead connection trenches is a laminated structure of the semiconductor layer and the second electrode layer in the structures disclosed in Patent Documents 1 and 2, it is difficult to improve connection reliability of the external connection terminal. Further, since every structure includes the semiconductor layer, there also arises a problem that it is difficult to reduce connection resistance of the external connection terminal.

In view of the circumstances as described above, it is an object of the present invention to provide a thin-film solar battery module and a method of manufacturing the thin-film solar battery module that are capable of improving connection reliability of an external connection terminal and reducing connection resistance of the external connection terminal.

### Means for Solving the Problem

In order to achieve the object described above, according to an embodiment of the present invention, there is provided a thin-film solar battery module including an insulating transparent substrate, a solar cell, and an external connection terminal. The solar cell includes a first electrode layer, a semiconductor layer, and a second electrode layer, the first electrode layer being formed on a surface of the transparent substrate, the semiconductor layer being formed on a surface of the first electrode layer, the second electrode layer being formed on a surface of the semiconductor layer. The external connection terminal includes a connection layer and a terminal layer and is arranged adjacently to the solar cell, the connection layer being formed on the surface of the first electrode layer and made of a single metal material layer, the terminal layer being laminated on the connection layer.

On the other hand, according to an embodiment of the present invention, there is provided a method of manufacturing a thin-film solar battery module, including forming a first electrode layer on an insulating transparent substrate. A semiconductor layer is formed on the first electrode layer. A first connection trench is formed in the semiconductor layer to have a depth at which the first connection trench reaches a surface of the first electrode layer. A second electrode layer is formed on the semiconductor layer including the first connection trench. A pair of second connection trenches are formed in the second electrode layer to have a depth at which the second connection trenches reach the surface of the first electrode layer such that the second connection trenches interpose the second electrode layer with which the first connection trench is filled. A conductive material is laminated on a region of the second electrode layer interposed between the pair of second connection trenches.

### BRIEF DESCRIPTION OF DRAWINGS

FIG. 1 are main part cross-sectional diagrams for describing processes of a method of manufacturing a thin-film solar battery module according to a first embodiment of the present invention;

FIG. 2(A) is a plan view showing the process of FIGS. 1 (A), and (B) and (C) are cross-sectional diagrams taken along directions of the line [B]-[B] and the line [C]-[C] in (A), respectively;

FIG. 3(A) is a plan view showing the process of FIGS. 1(C), and (B), (C), and (D) are cross-sectional diagrams taken along directions of the line [B]-[B], the line [C]-[C], and the line [D]-[D] in (A), respectively;

FIG. 4(A) is a plan view showing the process of FIGS. 1(E), and (B), (C), (D), and (E) are cross-sectional diagrams taken along directions of the line [B]-[B], the line [C]-[C], the line [D]-[D], and the line [E]-[E] in (A), respectively;

FIG. 5(A) is a plan view showing isolation trenches (second isolation trenches) formed in peripheral regions on long sides of a transparent substrate, and (B), (C), (D), and (E) are cross-sectional diagrams taken along directions of the line [B]-[B], the line [C]-[C], the line [D]-[D], and the line [E]-[E] in (A), respectively;

FIG. 6(A) is a plan view of FIGS. 1(F), and (B) and (C) are cross-sectional diagrams taken along directions of the line [B]-[B] and the line [C]-[C] in (A), respectively;

FIG. 7 is a plan view of FIG. 1(G);

FIG. 8 is a cross-sectional diagram showing a structure of an external connection terminal of a thin-film solar battery module according to another embodiment of the present invention; and

FIG. 9 is a cross-sectional diagram showing a structure of an external connection terminal of a thin-film solar battery module according to still another embodiment of the present invention.

### DETAILED DESCRIPTION

According to an embodiment of the present invention, there is provided a thin-film solar battery module including an insulating transparent substrate, a solar cell, and an external connection terminal. The solar cell includes a first electrode layer, a semiconductor layer, and a second electrode layer, the first electrode layer being formed on a surface of the transparent substrate, the semiconductor layer being formed on a surface of the first electrode layer, the second electrode layer being formed on a surface of the semiconductor layer. The external connection terminal includes a connection layer and a terminal layer and is arranged adjacently to the solar cell, the connection layer being formed on the surface of the first electrode layer and made of a single metal material layer, the terminal layer being laminated on the connection layer.

In the thin-film solar battery module, the connection layer is formed of a single metal material layer. Therefore, as compared to a case where the connection layer is constituted to contain a semiconductor material, the adhesiveness between the first electrode layer and the terminal layer can be enhanced and the contact resistance between the first electrode layer and the terminal layer can be reduced. With this, it is possible to improve the connection reliability of the external connection terminal and reduce the connection resistance of the external connection terminal.

The external connection terminal can be formed at each of positive and negative electrode portions within the solar cell. It should be noted that the number of connection layers to be formed is not particularly limited, and the external connection terminal can be formed of a single connection layer or a plurality of connection layers.

In the thin-film solar battery module, the connection layer can be formed of a constituent material of the second electrode layer.

With this, the connection layer can be formed at a time when the second electrode layer is formed in the manufacturing process of the solar cell.

In the thin-film solar battery module, the external connection terminal can be structured to include a terminal connection trench that connects the terminal layer to the first electrode layer.

With this, there is obtained a structure in which the first electrode layer and the terminal layer are brought into direct contact with each other, with the result that the connection resistance therebetween can be additionally reduced. Further, a bonding strength of the terminal layer in the external connection terminal is increased, with the result that the bonding reliability can be additionally improved.

In the thin-film solar battery module, the terminal connection trenches can be formed as a pair such that the connection layer is interposed between the terminal connection trenches.

With this, it is possible to more additionally improve the bonding reliability of the external connection terminal and an effect of reducing the connection resistance of the external connection terminal.

On the other hand, according to an embodiment of the present invention, there is provided a method of manufacturing a thin-film solar battery module, including forming a first electrode layer on an insulating transparent substrate. A semiconductor layer is formed on the first electrode layer. A first connection trench is formed in the semiconductor layer to have a depth at which the first connection trench reaches a surface of the first electrode layer. A second electrode layer is formed on the semiconductor layer including the first connection trench. A pair of second connection trenches are formed in the second electrode layer to have a depth at which the second connection trenches reach the surface of the first electrode layer such that the second connection trenches interpose the second electrode layer with which the first connection trench is filled. A conductive material is laminated on a region of the second electrode layer interposed between the pair of second connection trenches.

By filling the first connection trench with the second electrode layer, the connection layer in the thin-film solar battery module according to the present invention is structured. The connection layer is formed of a constituent material of the second electrode layer. Therefore, when a metal material is used for the constituent material of the second electrode layer, the connection layer is formed of the metal material. With this, it is possible to improve the connection reliability of the external connection terminal and reduce the connection resistance of the external connection terminal.

In the method of manufacturing a thin-film solar battery module, the second connection trenches may be filled with the conductive material such that the conductive material straddles the region of the second electrode layer.

With this, it is possible to more additionally improve the bonding reliability of the external connection terminal and an effect of reducing the connection resistance of the external connection terminal.

Hereinafter, embodiments of the present invention will be described with reference to the drawings.

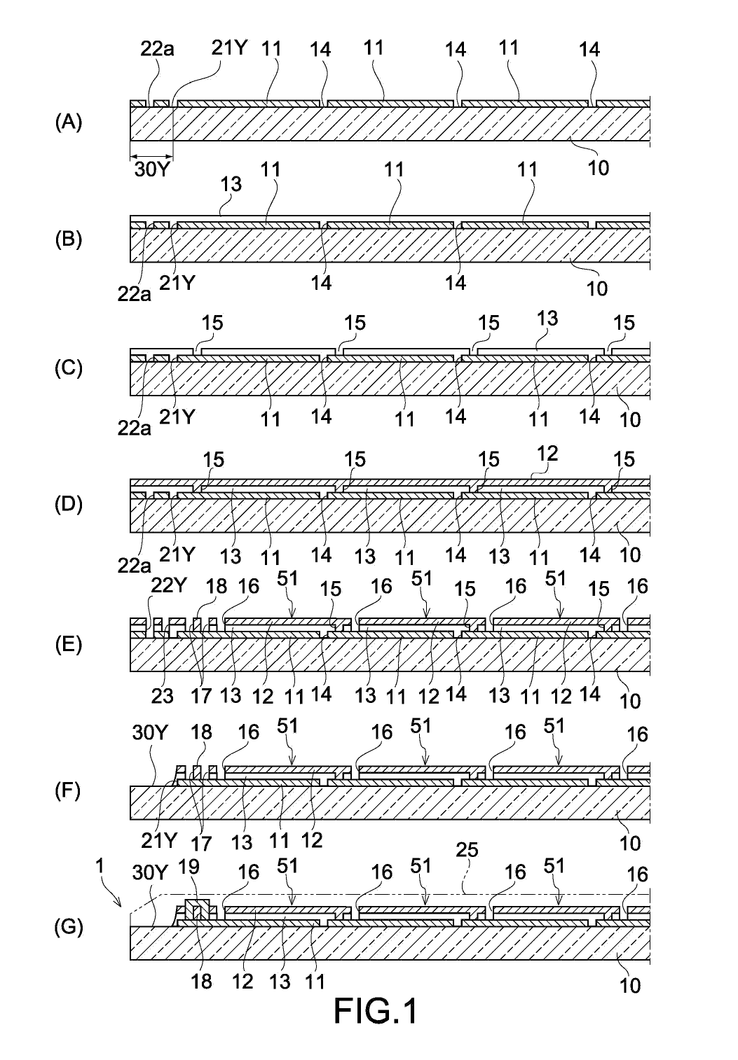

FIG. 1 are main part cross-sectional diagrams for describing processes of a method of manufacturing a thin-film solar battery module according to an embodiment of the present invention.

(Process of FIG. 1(A))

First, as shown in FIG. 1(A), a transparent electrode layer 11 is formed as a first electrode layer on an insulating transparent substrate 10.

The transparent substrate 10 has a rectangular shape and is typically a glass substrate. A plastic substrate or a ceramic substrate can also be used other than the glass substrate. Further, the transparent electrode layer 11 (TCO:

Transparent Conductive Oxide) is formed of a transparent conductive film made of an ITO (Indium Tin Oxide), SnO₂, ZnO, or the like. The transparent electrode layer 11 is formed in a predetermined thickness on the entire surface of the transparent substrate 10 by a CVD method, a sputtering method, a coating method, or the like.

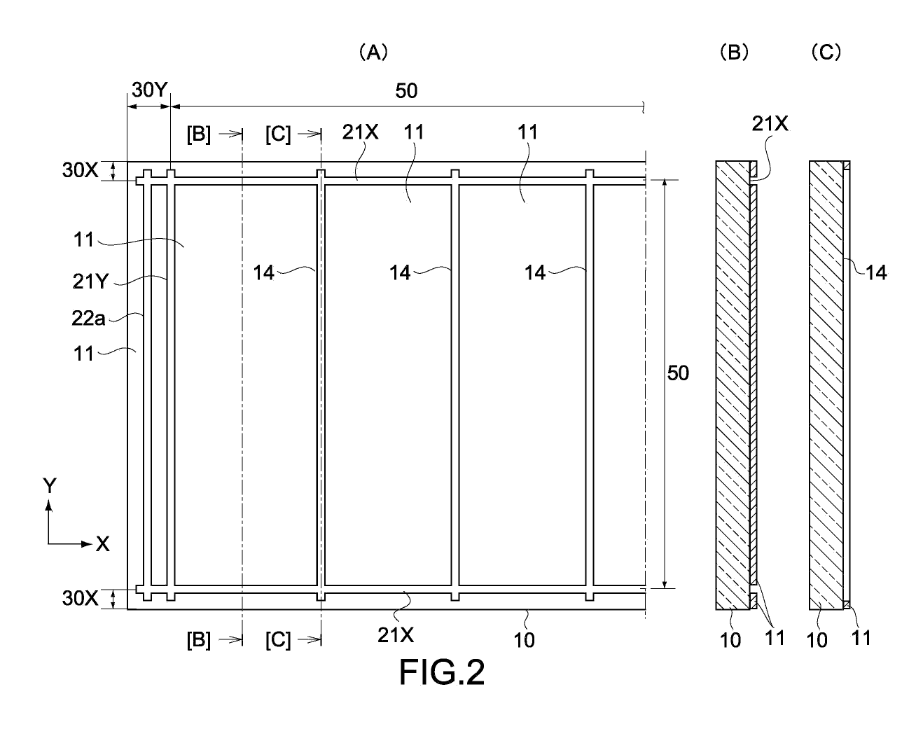

FIG. 2(A) is a plan view of FIG. 1(A). After the transparent electrode layer 11 is formed, the transparent electrode layer 11 is laser-scribed to form electrode isolation trenches 14, region isolation trenches 21X and 21Y, and isolation trenches 22a. FIGS. 2(B) and (C) are cross-sectional diagrams taken along directions of the line [B]-[B] and the line [C]-[C] in FIG. 2(A), respectively. The region isolation trench 21X is intended to reduce an influence of processing damage in a peripheral region on module characteristics. The number of region isolation trenches 21X to be formed may be one on each long side of the substrate 10, or may be 2 or more. The increased number of trenches is effective in reducing the influence of processing damage in the peripheral region on module characteristics, but a cell area that is effective in power generation is reduced.

A plurality of electrode isolation trenches 14 are formed in parallel to each other at arbitrary intervals along a Y direction of the transparent substrate 10 (short-side direction of transparent substrate 10).

The region isolation trench 21X is for isolating a peripheral region 30X on each long side of the transparent substrate 10 and a power generation region 50 on an inner side of the peripheral region 30X. The region isolation trench 21X is formed along an X direction (long-side direction of transparent substrate 10).

The other region isolation trench 21Y is for isolating a peripheral region 30Y on each short side of the transparent substrate 10 and the power generation region 50 on an inner side of the peripheral region 30Y. The region isolation trench 21Y is formed along the Y direction (short-side direction of transparent substrate 10).

Those region isolation trenches 21X and 21Y are formed to have a depth at which each of the trenches reaches the surface of the transparent substrate 10.

The isolation trench 22a is formed at a position closer to the peripheral region 30Y side than the region isolation trench 21Y. The isolation trench 22a is formed to have a depth at which the isolation trench 22a reaches the surface of the transparent substrate 10. The position at which the isolation trench 22a is formed is not particularly limited as long as the position falls within the peripheral region 30Y.

The laser scribing is to apply a light beam from a front surface side or a back surface side of the transparent substrate 10 to remove a predetermined region of the transparent electrode layer 11, in which a laser wavelength or an oscillation output is set appropriately depending on the type of a material to be removed, or the like. The laser beam may be a continuous laser beam or may be a pulse laser beam that causes less thermal damage to the device. It should be noted that the above description also applies to the laser scribing for a semiconductor layer 13 and a backside electrode layer 12 to be described later.

(Process of FIG. 1(B))

Next, as shown in FIG. 1(B), a semiconductor layer 13 is formed on the entire surface of the transparent substrate 10 on which the transparent electrode layer 11 is formed. The semiconductor layer 13 is embedded also in the electrode isolation trenches 14 formed in the transparent electrode layer 11.

The semiconductor layer 13 is formed of a laminated body of a p-type semiconductor film, an i-type semiconductor film, and an n-type semiconductor film. In this embodiment, the p-type semiconductor film is formed of a p-type amorphous silicon film, the i-type semiconductor film is formed of an i-type amorphous silicon film, and the n-type semiconductor film is formed of an n-type microcrystalline silicon film. In the above example, the amorphous silicon film can be changed for a microcrystalline silicon film, and the microcrystalline silicon film can be changed for an amorphous silicon film as appropriate. The semiconductor layer 13 may be a tandem type or a triple type in which a plurality of units (pin, pinp, npin, . . . , etc.) including a plurality of power generation layers are laminated, and may be provided with intermediate layers between the power generation layers at that time. The semiconductor films described above can be formed by a plasma CVD method. The thickness of each semiconductor film is not particularly limited and is set as appropriate in accordance with the specifications.

(Process of FIG. 1(C))

Subsequently, as shown in FIG. 1(C), connection trenches 15 are formed in a predetermined region of the semiconductor layer 13. Each of the connection trenches 15 has a depth at which the connection trench 15 reaches the surface of the transparent electrode layer 11 as a coating layer. It should be noted that the connection trenches 15 each correspond to a “first connection trench” according to the present invention.

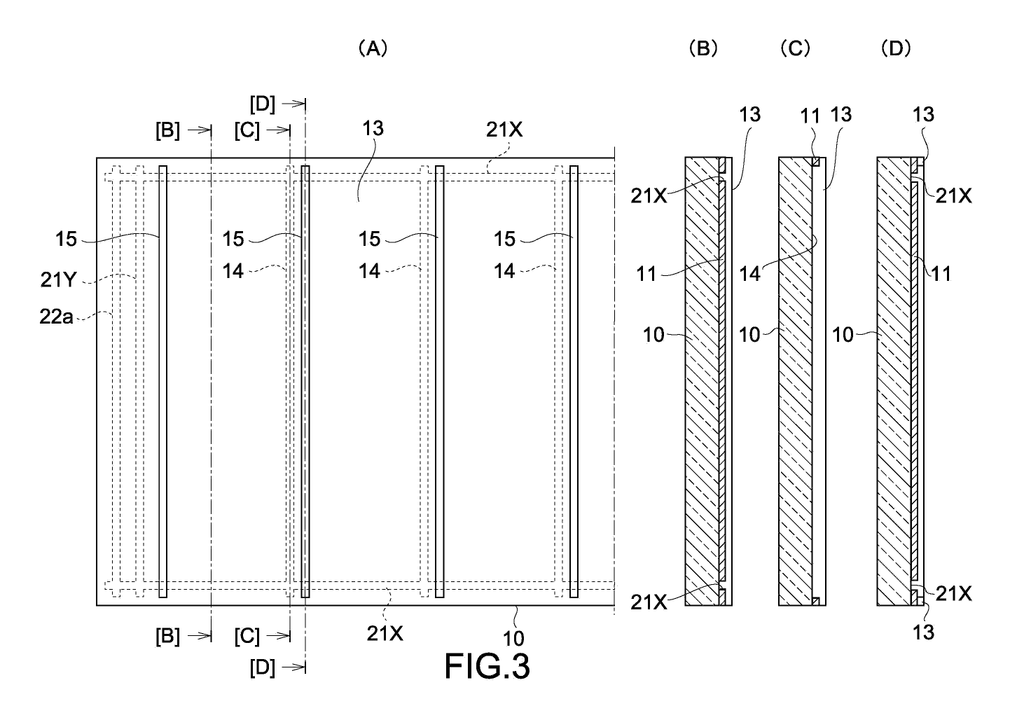

FIG. 3(A) is a plan view of FIG. 1(C). After the semiconductor layer 13 is formed, the semiconductor layer 13 is laser-scribed to form the connection trenches 15. FIGS. 3(B), (C), and (D) are cross-sectional diagrams taken along directions of the line [B]-[B], the line [C]-[C], and the line [D]-[D] in FIG. 3(A), respectively.

(Process of FIG. 1(D))

Next, as shown in FIG. 1(D), a backside electrode layer 12 is formed as a second electrode layer on the entire surface of the transparent substrate 10 on which the transparent electrode layer 11 and the semiconductor layer 13 are formed. The backside electrode layer 12 is embedded also in the connection trenches 15 formed in the semiconductor layer 13.

The backside electrode layer 12 is formed of a ZnO layer and an Ag layer having excellent light reflection characteristics in this embodiment, but it can be formed of other metal such as Al, Cr, Mo, W, and Ti, or an alloy film instead of the Ag layer. The transparent electrode layer 11 is formed on the entire surface of the transparent substrate 10 in a predetermined thickness by a CVD method, a sputtering method, a coating method, or the like.

(Process of FIG. 1(E))

Subsequently, as shown in FIG. 1(E), predetermined regions of the backside electrode layer 12 are laser-scribed to form device isolation trenches 16, terminal connection trenches 17, isolation trenches 22Y, and boundary isolation trenches 23.

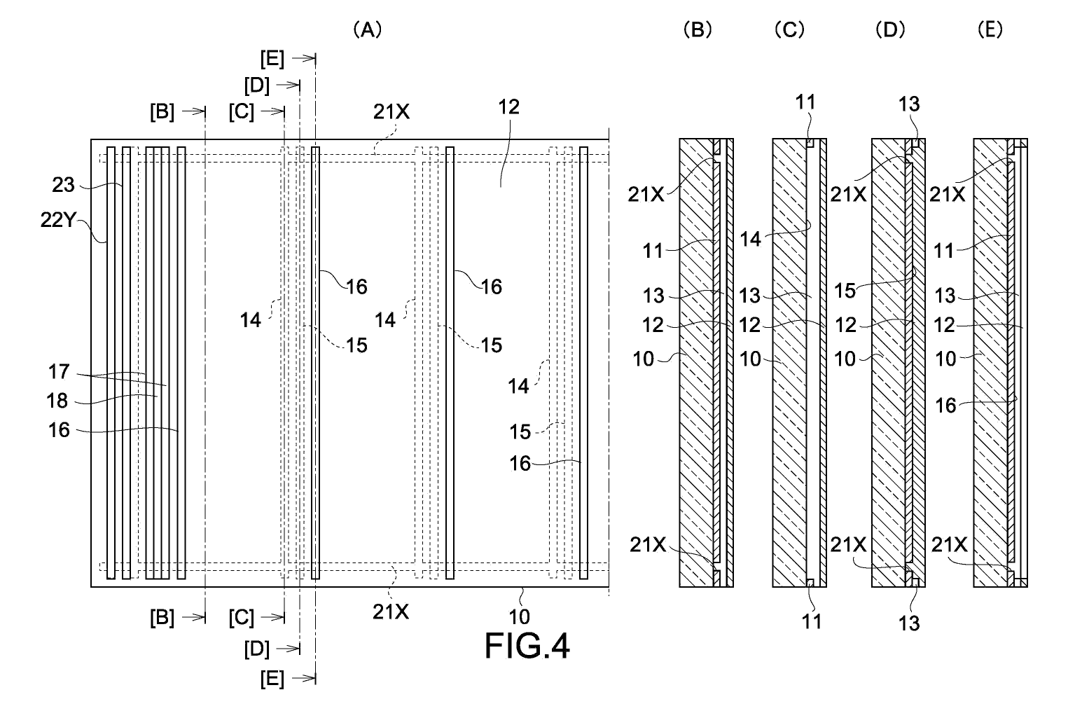

The device isolation trenches 16 are formed to have a depth at which each device isolation trench 16 reaches the surface of the transparent electrode layer 11. FIG. 4(A) is a plan view of FIG. 1(E). FIGS. 4(B), (C), (D), and (E) are cross-sectional diagrams taken along directions of the line [B]-[B], the line [C]-[C], the line [D]-[D], and the line [E]-[E] in FIG. 4(A), respectively.

The terminal connection trenches 17 are connection trenches for connecting terminal layers 19 described later to the transparent electrode layer 11, the terminal connection trenches 17 being formed in predetermined positions of the power generation region 50 that face the peripheral region 30Y of the transparent substrate 10. The terminal connection trenches 17 are formed as a pair to have a depth at which each terminal connection trench 17 reaches the surface of the transparent electrode layer 11, by laser-scribing the backside electrode layer 12 and the semiconductor layer 13 such that the connection trench 15 formed in the semiconductor layer 13 and embedded with a backside electrode material is interposed between the terminal connection trenches 17. The terminal connection trenches 17 are similarly formed in not only one peripheral region 30Y side shown in the figures but also the other peripheral region side not shown. It should be noted that the terminal connection trenches 17 each correspond to a “second connection trench” according to the present invention.

Further, a terminal connection layer 18 made of a backside electrode material that is interposed between the terminal connection trenches 17 is formed simultaneously with the formation of the terminal connection trenches 17. The terminal connection layer 18 is constituted of a structure formed linearly in parallel to the short-side direction of the transparent substrate 10. A width of the terminal connection layer 18 is not particularly limited. Further, the number of terminal connection layers 18 to be formed may not be limited to one that is shown in the figure, but the number may be two or more (see FIG. 9).

The isolation trench 22Y is formed by laser-scribing the backside electrode layer 12 and the semiconductor layer 13 at the same position as that of the isolation trench 22a (FIG. 1(A)) that is formed in the transparent electrode layer 11 in the peripheral region 30Y. The isolation trench 22Y is formed to have a depth at which the isolation trench 22Y reaches the surface of the transparent substrate 10 in the peripheral region 30Y on each short side of the transparent substrate 10.

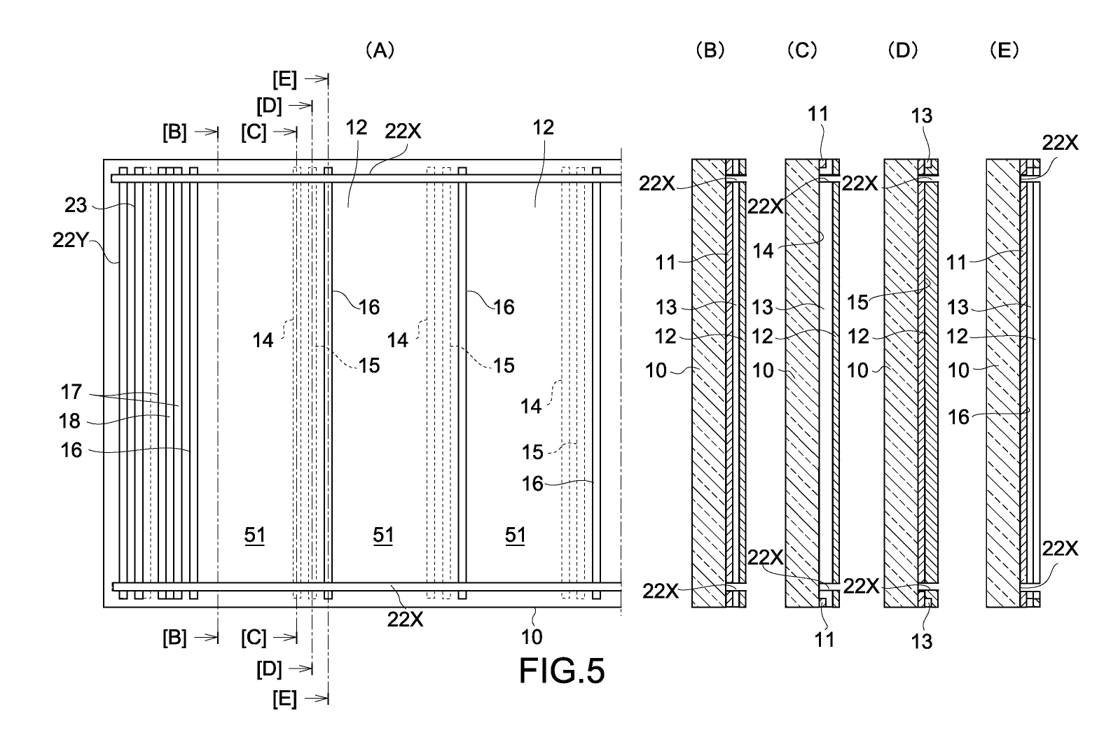

The isolation trenches described above are formed in not only the peripheral regions 30Y on the short sides of the transparent substrate 10 but also the peripheral regions 30X on long sides thereof. FIG. 5(A) is a plan view showing isolation trenches 22X formed in the peripheral regions 30X on the long sides of the transparent substrate 10. Further, FIGS. 5(B), (C), (D), and (E) are cross-sectional diagrams taken along directions of the line [B]-[B], the line [C]-[C], the line [D]-[D], and the line [E]-[E] in FIG. 5(A), respectively. The isolation trenches 22X are formed to have a depth at which each isolation trench 22X reaches the surface of the transparent substrate 10.

The boundary isolation trench 23 is formed by laser-scribing the backside electrode layer 12 and the semiconductor layer 13 at a predetermined position located inwardly from the isolation trench 22Y in each of the peripheral regions 30Y of the transparent substrate 10. The boundary isolation trench 23 is formed to have a depth at which the boundary isolation trench 23 reaches the surface of the transparent electrode layer 11 in this embodiment, but the boundary isolation trench 23 is not limited thereto. The boundary isolation trench 23 may be formed to have a depth at which the boundary isolation trench 23 reaches the surface of the transparent substrate 10. The boundary isolation trench 23 forms a boundary between a blast region and a non-blast region in a blast treatment process to be described later.

Through the above process of forming the isolation trenches 22X and 22Y, a plurality of solar cells 51 are structured in the power generation region 50. In each of the solar cells 51, the backside electrode layer 12 is electrically connected to the transparent electrode layer 11 of another adjacent cell via the connection trench 15. The module structure in which the solar cells 51 are connected to each other in series as in this embodiment can be applied to a power generation module in which a generated current is sufficient but a generated voltage is relatively low. On the other hand, a module structure in which solar cells are connected in parallel to each other can be applied to a power generation module in which a generated voltage is sufficient but a generated current is relatively low.

(Process of FIG. 1(F))

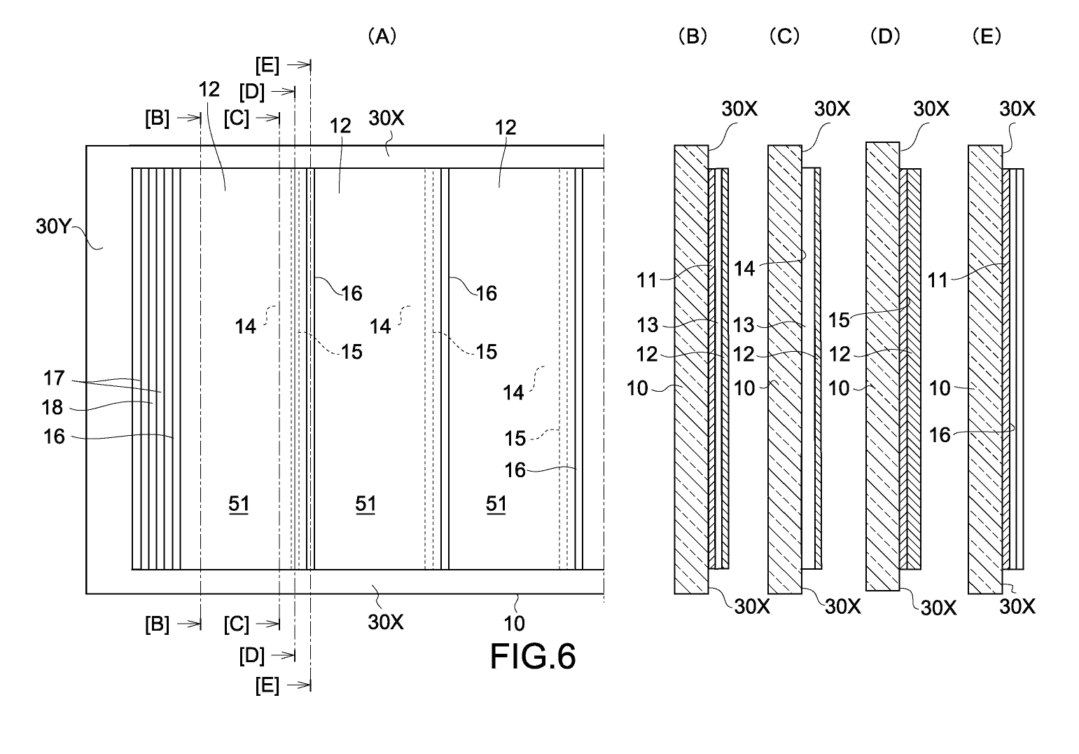

Next, as shown in FIG. 1(F) and FIG. 6, the peripheral regions 30X and 30Y of the transparent substrate 10 are subjected to blast treatment. As a result, the transparent electrode layer 11, the semiconductor layer 13, and the backside electrode layer 12 on the peripheral regions 30X and 30Y are removed. FIG. 6(A) is a plan view of FIG. 1(F), and FIGS. 6(B) and (C) are cross-sectional diagrams taken along directions of the line [B]-[B] and the line [C]-[C] in FIG. 2(A), respectively.

Conditions of the blast treatment are not particularly limited as long as the transparent electrode layer 11, the semiconductor layer 13, and the backside electrode layer 12 on the peripheral regions 30X and 30Y can be appropriately removed. Blast particles are not limited to ceramic particles such as alumina particles and silica particles, and metal-based particles or plant-based particles may be used therefor. Further, at a time of the blast treatment, the surface of the transparent substrate 10 may be subjected to masking such that the blast particles are not applied to the power generation region 50.

Further, in this embodiment, the semiconductor layer 13 that is embedded in the region isolation trenches 21X and 21Y for isolating the peripheral regions 30X and 30Y from the power generation region 50 is not completely removed, and is left so as to cover the circumference of the transparent electrode layer 11 as shown in FIG. 1(F). As a result, the circumference of the transparent electrode layer 11 is prevented from being directly exposed to the outside.

(Process of FIG. 1(G))

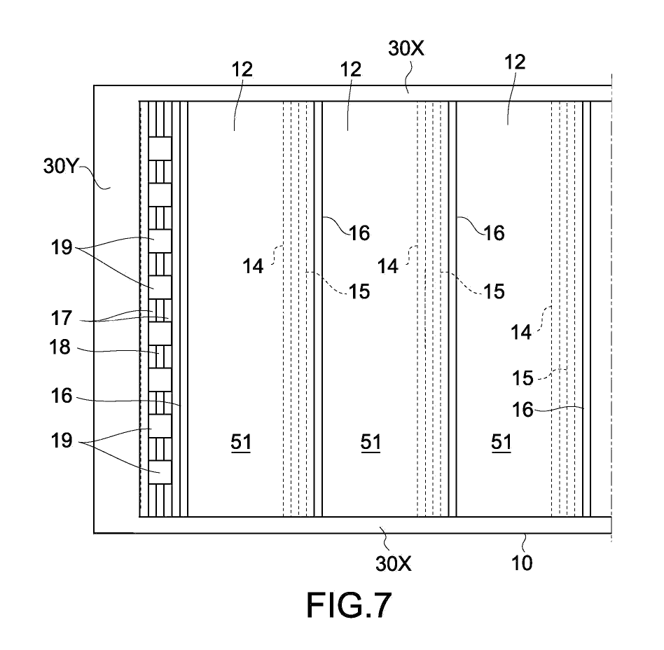

Subsequently, as shown in FIG. 1(G) and FIG. 7, terminal layers 19 are formed by embedding a conductive material in the terminal connection trenches 17. The terminal layers 19 are laminated on the terminal connection layer 18 so as to straddle the terminal connection layer 18. In this embodiment, the terminal layers 19 are formed at intervals along an extending direction of the terminal connection layer 18 as shown in FIG. 7. The terminal layers 19 are formed at side portions on both the short sides of the transparent substrate 10. It should be noted that the terminal layers 19 may be continuously formed over the entire formation region of the terminal connection layer 18.

The terminal layers 19 can be formed using appropriate methods such as a method of using a conductive adhesive, a method of forming a metal plating layer made of Cu or the like, and a method of pressure-bonding a metal block onto a substrate, in addition to a method of applying a molten solder or a method of performing reflowing after applying a solder paste.

As described above, an external connection terminal 52 for taking out a voltage generated in the solar cells 51 to the outside is manufactured on the surface of the transparent substrate 10. The external connection terminal 52 is manufactured, as each of positive and negative electrode portions, at two positions at which a potential difference therebetween within the integrated solar cells is highest. In this embodiment, those external connection terminals 52 are arranged at both side portions on the short sides of the transparent substrate 10 adjacently to the solar cells. For example, the external connection terminals 52 are connected to electrode portions of an external device such as a capacitor (not shown).

Lastly, a sealing layer 25 made of an insulating resin that covers the entire surface of the transparent substrate 10 (FIG. 1(G)) is formed, thus sealing the solar cells 51 on the transparent substrate 10. Further, corner portions of the circumference of the transparent substrate 10 are chamfered as appropriate. The chamfering process is performed for the purpose of preventing breakage of the transparent substrate 10 at a time of handling or processing among processes. Therefore, the chamfering process may be performed, though not limited to the last process, before a process of forming the transparent electrode layer 11 or among arbitrary processes.

It should be noted that in order to connect the external connection terminal 52 to the outside, a surface of the external connection terminal 52 can be exposed from a surface of the sealing layer 25. Further, it may be possible to form, after a bonding wire is connected to the external connection terminal 52, the sealing layer 25 with a part of the bonding wire being exposed to the outside.

As described above, the thin-film solar battery module 1 including the plurality of solar cells 51 that are integrated on the transparent substrate 10 is manufactured. The thin-film solar battery module 1 is installed with the transparent substrate 10 side as a light-incident surface. Sunlight that enters from the transparent substrate 10 enters the semiconductor layer 13 via the transparent electrode layer 11, and the semiconductor layer 13 causes a photoelectric conversion effect in accordance with the incident light. A voltage generated in the semiconductor layer 13 is taken by the transparent electrode layer 11 and the backside electrode layer 12 and supplied to an external capacitor (not shown) via the external connection terminal 52.

In this embodiment, the terminal connection layer 18 constituting the external connection terminal 52 is formed of a single metal material layer. Therefore, as compared to a case where the terminal connection layer 18 is constituted to contain a semiconductor material, the adhesiveness between the transparent electrode layer 11 and the terminal connection layer 18 can be enhanced and the contact resistance between the transparent electrode layer 11 and the terminal connection layer 18 can be reduced. With this, it is possible to improve the connection reliability of the external connection terminal 52 and reduce the contact resistance of the external connection terminal 52.

In the thin-film solar battery module 1 of this embodiment, the terminal connection layer 18 is formed of a constituent material of the backside electrode layer 12. With this, the terminal connection layer 18 can be formed at a time when the backside electrode layer 12 is formed in the manufacturing process of the solar cells 51.

In the thin-film solar battery module 1 of this embodiment, the external connection terminal 52 includes the terminal connection trenches 17 for connecting the terminal layers 19 to the transparent electrode layer 11. With this, there is obtained a structure in which the transparent electrode layer 11 and the terminal layers 19 are brought into direct contact with each other, with the result that the connection resistance therebetween can be additionally reduced. Further, a bonding strength of the terminal layers 19 is increased, with the result that the bonding reliability of the external connection terminal 52 can be additionally improved.

In the thin-film solar battery module 1 of this embodiment, the terminal connection trenches 17 are formed as a pair so that the terminal connection layer 18 is interposed therebetween. With this, the improvement of the bonding reliability of the external connection terminal 52 and the effect of reducing the connection resistance can be additionally enhanced.

Further, since the terminal layers 19 are formed so as to straddle the terminal connection layer 18, the terminal layers 19 and the transparent electrode layer 11 can be electrically connected reliably, and the contact resistance therebetween can be reduced. In addition, in a series-connection-type thin-film solar battery module 1, a great reduction in loss of a generated voltage can be achieved.

On the other hand, in this embodiment, after the isolation trenches 22X and 22Y are additionally formed on outer sides of the region isolation trenches 21X and 21Y (peripheral region 30X side and peripheral region 30Y side), the peripheral regions 30X and 30Y including the isolation trenches 22X and 22Y are subjected to the blast treatment to remove the transparent electrode layer 11, the semiconductor layer 13, and the backside electrode layer 12 on the peripheral regions. With this, even when the isolation trenches 22X and 22Y are not appropriately formed or residues of the conductive material remain in the isolation trenches 22X and 22Y, a dielectric breakdown voltage between the peripheral regions 30X and 30Y and the power generation region 50 can be secured in a subsequent blast treatment process.

Thus, according to this embodiment, the peripheral regions 30X and 30Y and the power generation region 50 in the thin-film solar battery module 1 can be electrically isolated from each other reliably, with the result that it is possible to secure dielectric breakdown voltage characteristics of high reliability with respect to the infiltration of moisture or the like from the outside, the moisture intervening between the transparent substrate 10 and the sealing layer 25.

Further, the electric isolation treatment between the peripheral regions 30X and 30Y and the power generation region 50 is performed in two processes, the process of forming the isolation trenches 22X and 22Y with respect to the peripheral regions and the blast treatment process. Therefore, even when one treatment is imperfectly performed, the imperfection thereof can be compensated with the other treatment. As a result, it is possible to reduce a load on control of process in the both treatment.

Further, in this embodiment, the isolation trench 22a is formed in advance at a corresponding position of the transparent electrode layer 11 at a time when the isolation trench 22X is formed. With this, the transparent electrode layer 11 that is difficult to be removed by laser scribing as compared to the semiconductor layer 13 is unnecessary to be removed when the isolation trench 22Y is formed, with the result that the isolation trench 22X of high reliability can be stably formed.

Further, in this embodiment, the boundary isolation trench 23 is formed between the region isolation trench 21Y and the isolation trench 22Y. With this, it is possible to further enhance the reliability of the isolation between the peripheral region 30Y and the power generation region 50 at the time of the blast treatment, and to enhance shape accuracy of a boundary portion between the blast treatment region and the non-blast region after the blast treatment.

Further, in this embodiment, the semiconductor layer 13 that is embedded in the region isolation trench 21Y for isolating the peripheral region 30Y from the power generation region 50 is not completely removed, and is left so as to cover the circumference of the transparent electrode layer 11 as shown in FIG. 1(F). With this, the circumference of the transparent electrode layer 11 is prevented from being exposed to the outside, and since the semiconductor layer 13 has higher resistance than the transparent electrode layer 11, the dielectric breakdown voltage between the circumference of the transparent electrode layer 11 and the peripheral region 30Y can be additionally improved.

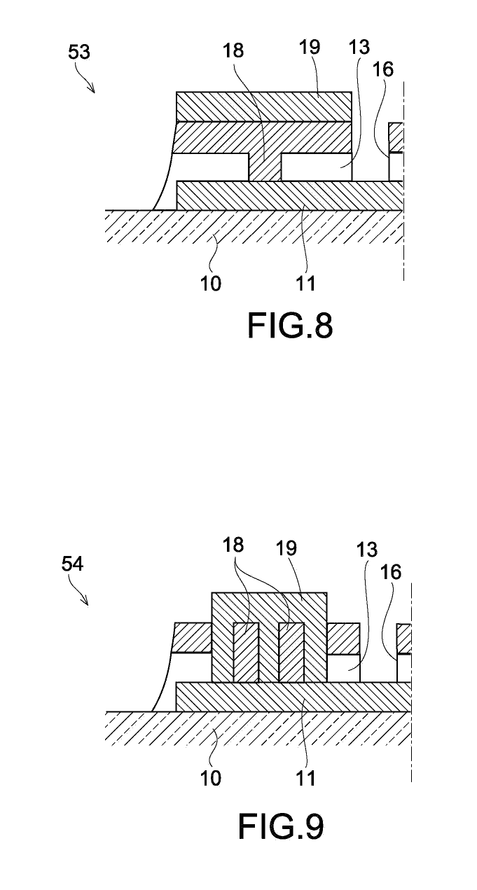

FIG. 8 is a cross-sectional diagram showing a structure of an external connection terminal 53 of a thin-film solar battery module according to another embodiment of the present invention. It should be noted that portions in the figures that correspond to those in FIG. 1 are denoted by the same reference symbols and detailed descriptions thereof are omitted.

The external connection terminal 53 of this embodiment has a structure in which, after the terminal connection layer 18 is formed, the terminal layers 19 are laminated on the terminal connection layer 18 without forming the terminal connection trenches 17. Also in this example, the terminal layers 19 are connected to the transparent electrode layer 11 via the terminal connection layer 18 made of a single metal material layer, with the result that similarly to the description above, it is possible to obtain the external connection terminal 53 that is excellent in the connection reliability and has low electric resistance characteristics. Further, the process of forming the terminal connection trenches 17 can be omitted, with the result that the number of man-hours for manufacturing the external connection terminal 53 and the manufacturing costs thereof can be reduced.

FIG. 9 is a cross-sectional diagram showing a structure of an external connection terminal 54 of a thin-film solar battery module according to still another embodiment of the present invention. It should be noted that portions in the figures that correspond to those in FIG. 1 are denoted by the same reference symbols and detailed descriptions thereof are omitted.

The external connection terminal 54 of this embodiment has two terminal connection layers 18 provided at intervals. The number of terminal connection layers 18 to be formed can be arbitrarily set by only changing the number of terminal connection trenches 17 to be formed.

Also in this example, the terminal layers 19 are connected to the transparent electrode layer 11 via the terminal connection layer 18 made of a single metal material layer, with the result that similarly to the description above, it is possible to obtain the external connection terminal 53 that is excellent in the connection reliability and has low electric resistance characteristics. In particular, since the plurality of terminal connection layers 18 are formed, the connection resistance between the terminal layers 19 and the transparent electrode layer 11 can be reduced as compared to the embodiment of FIG. 1. With this, it is possible to reduce the resistance of the external connection terminal 54.

Though the embodiments of the present invention have been described up to here, the present invention is not limited to the embodiments described above, and various changes can of course be added without departing from the gist of the present invention.

For example, a formed width of each of the electrode isolation trenches 14, the connection trenches 15, the device isolation trenches 16, the terminal connection trenches 17, the region isolation trenches 21X and 21Y, the isolation trenches 22a, 22X, and 22Y, and the boundary isolation trenches 23 is not particularly mentioned in the embodiments described above. However, those trench widths can be set as appropriate based on the specifications of the thin-film solar battery module 1, laser oscillation conditions of laser scribing, or the like.

Further, though the method of manufacturing the thin-film solar battery module 1 in which the solar cells 51 are connected to each other in series has been described as an example in the embodiments described above, the present invention is not limited thereto. The present invention is also applicable to manufacture of a thin-film solar battery module in which solar cells are connected in parallel to each other.

What is claimed is:

1. A thin-film solar battery module, comprising:
an insulating transparent substrate;
a solar cell including a first electrode layer, a semiconductor layer, and a second electrode layer, the first electrode layer being formed on a surface of the transparent substrate, the semiconductor layer being formed on a surface of the first electrode layer, the second electrode layer being formed on a surface of the semiconductor layer; and
an external connection terminal that includes a connection layer and a terminal layer and is arranged adjacently to the solar cell, the connection layer being formed on the surface of the first electrode layer and made of a single metal material layer, the terminal layer being laminated on the connection layer.

2. The thin-film solar battery module according to claim 1,
wherein the connection layer is formed of a constituent material of the second electrode.

3. The thin-film solar battery module according to claim 1,
wherein the external connection terminal includes a terminal connection trench that connects the terminal layer to the first electrode layer.

4. The thin-film solar battery module according to claim 3,
wherein the terminal connection trenches are formed as a pair such that the connection layer is interposed between the terminal connection trenches.

5. The thin-film solar battery module according to claim 1,
wherein the terminal layer is formed of a solder material or a conductive adhesive.

6. A method of manufacturing a thin-film solar battery module, comprising:
forming a first electrode layer on an insulating transparent substrate;
forming a semiconductor layer on the first electrode layer;
forming a first connection trench in the semiconductor layer to have a depth at which the first connection trench reaches a surface of the first electrode layer;
forming a second electrode layer on the semiconductor layer including the first connection trench;
forming a pair of second connection trenches in the second electrode layer to have a depth at which the second connection trenches reach the surface of the first electrode layer such that the second connection trenches interpose the second electrode layer with which the first connection trench is filled; and
laminating a conductive material on a region of the second electrode layer interposed between the pair of second connection trenches.

7. The method of manufacturing a thin-film solar battery module according to claim 6,
wherein the second connection trenches are filled with the conductive material such that the conductive material straddles the region of the second electrode layer.
